(19) United States
(12) Patent Application Publication
(10) Pub. No.: US 2011/0249832 A1
(43) Pub. Date: Oct. 13, 2011

(54) SPEAKER DEVICE

(75) Inventors: Nobukazu Suzuki, Kanagawa (JP); Yoshio Ohashi, Kanagawa (JP); Kazuo Ichikawa, Kanagawa (JP); Tetsu Sumii, Kanagawa (JP); Edward Barber, London (GB); Jay Osgerby, London (GB)

(73) Assignee: Sony Corporation, Tokyo (JP)

(21) Appl. No.: 13/083,968

(22) Filed: Apr. 11, 2011

(30) Foreign Application Priority Data
Apr. 12, 2010 (JP) P2010-091553

(51) Int. Cl. H03F 99/00; H04R 1/02

(52) U.S. Cl. 381/120; 381/386

(57) ABSTRACT

A speaker device includes: a casing having a cylindrical shape which opens at one end side; and a sounding body arranged at the other end side of the casing and driven based on an audio signal, wherein a sealed space is formed by the casing and a setting surface when the casing is set, which functions as a cabinet.

### BACKGROUND OF THE INVENTION

1. Field of the Invention

The present invention relates to a speaker device, which is suitable for being applied to a speaker device in which objects can be put inside a cabinet.

2. Description of the Related Art

In related art, there is proposed a speaker in which an ornamental object is housed in a cubic transparent casing and a speaker body is fixed to a surface of the transparent casing to thereby add an ornamental feature (for example, refer to Japanese Utility Model Registration No. 3105852 (Patent Document 1)).

### SUMMARY OF THE INVENTION

As the speaker described in Patent Document 1 has a structure of having an opening and closing door, there exist problems that there is little degree of freedom for taking in/out the ornamental object and that, when the transparent casing is formed in a particular shape, it is difficult to perform processing, molding and so on due to the existence of a bottom surface.

Also in the speaker described in Patent Document 1, a speaker unit itself is not transparent though the transparent casing is used, therefore, the speaker is not completely transparent and there is a problem that the ornamental object is not seen well by being interrupted by the speaker unit.

In view of the above, it is desirable to provide a speaker device having a simple structure in which an object can be put inside the speaker device.

According to an embodiment of the invention, there is provided a speaker device including a casing having a cylindrical shape which opens at one end side and a sounding body arranged at the other end side of the casing and driven based on an audio signal, in which a sealed space is formed by the casing and a setting surface when the casing is set, which functions as a cabinet. According to the structure, a bottom surface is not necessary to thereby simplify the structure as well as it is easy to put an object inside the casing.

According to the embodiment of the invention, the speaker device includes a casing having a cylindrical shape which opens at one end side and a sounding body arranged at the other end side of the casing and driven based on an audio signal, in which a sealed space is formed by the casing and a setting surface when the casing is set, which functions as a cabinet. According to the structure, the bottom surface is not necessary to thereby simplify the structure as well as it is easy to put an object inside the casing, as a result, it is possible to realize the speaker device having the simple structure in which an object can be put inside the device.

### BRIEF DESCRIPTION OF THE DRAWINGS

FIG. 1 is a schematic perspective view showing a whole appearance structure (1) of a speaker device;

FIG. 2 is a schematic perspective view showing a whole appearance structure (2) of the speaker device;

FIG. 3 is a schematic perspective view showing a whole appearance structure (3) of the speaker device;

FIG. 4 is a cross-sectional perspective view showing a cross-sectional structure of the speaker device;

FIG. 5 is a perspective bottom surface view showing a bottom surface structure of a lower body in a body portion;

FIGS. 6A to 6D are an upper surface view, side surface views and a bottom surface view showing the appearance structure of the speaker device;

FIG. 7 is a schematic view showing a structure of an end portion of a transparent casing;

FIG. 8 is a schematic block diagram showing a configuration (1) of a drive system;

FIG. 9 is a schematic block diagram showing a configuration (2) of the drive system;

FIG. 10 is a schematic perspective view for explaining a state of displaying an object inside the transparent casing;

FIG. 11 is a schematic perspective view showing sound image localization when using only a speaker unit;

FIG. 12 is a schematic perspective view showing sound image localization when using the transparent casing as a cabinet doubling as a diaphragm;

FIG. 13 is a perspective cross-sectional view showing a state in which light is propagated inside the cabinet to irradiate the setting surface; and

FIG. 14 is a schematic perspective view showing a lighting state of illumination.

### DESCRIPTION OF THE PREFERRED EMBODIMENTS

Hereinafter, embodiments of the invention will be explained. The explanation will be made in the following order.

1. Embodiment

2. Other embodiments

### 1. Embodiment

### [1-1. Structure of a Speaker Device]

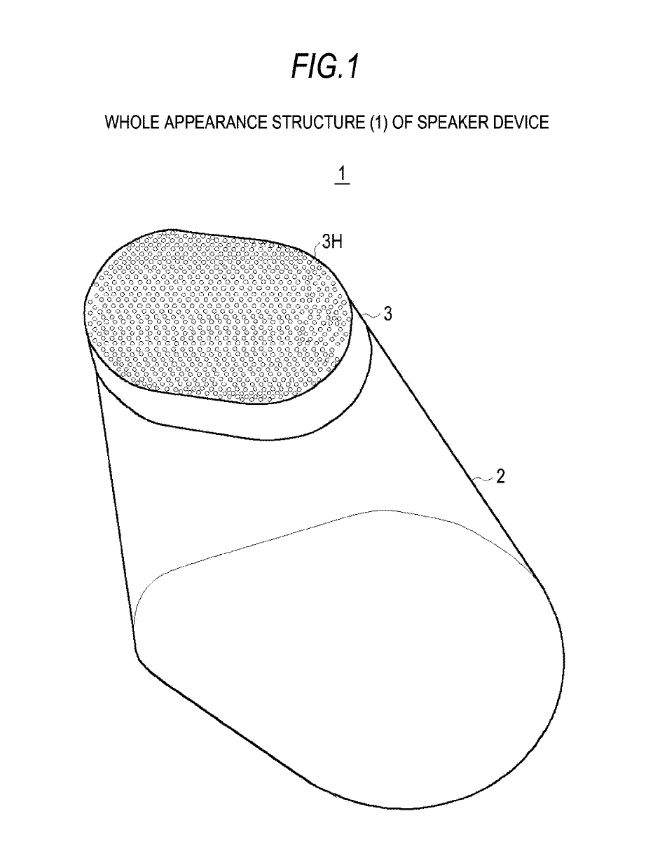

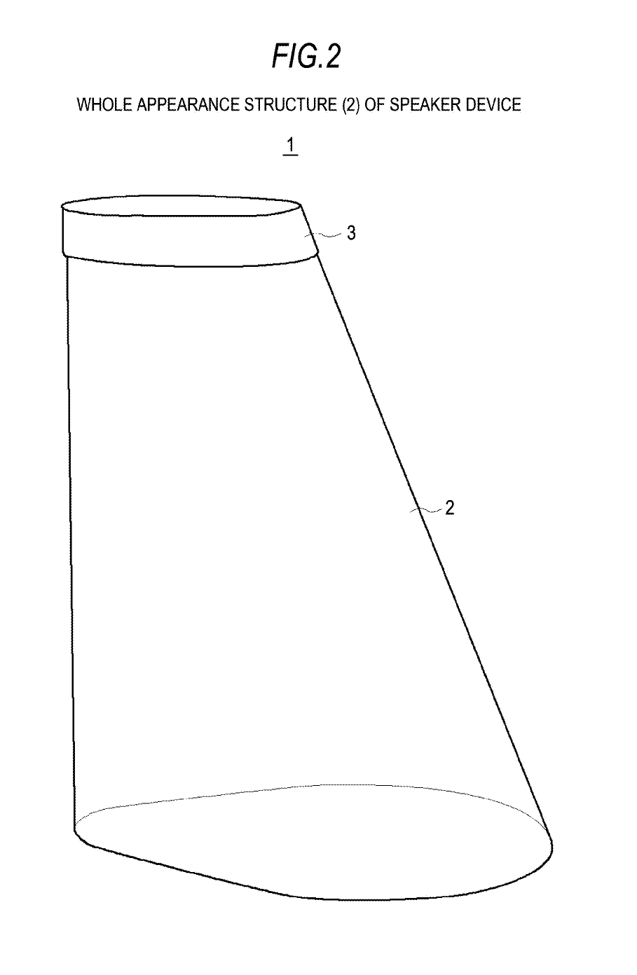

As shown in FIG. 1 to FIG. 5, a speaker device 1 includes a transparent casing 2 having a shape which is an approximately cylindrical viewed as a whole and becomes gradually wide toward a bottom hem thereof and a body portion 3 having an approximately elliptical shape with a given thickness, which is put over the transparent casing 2.

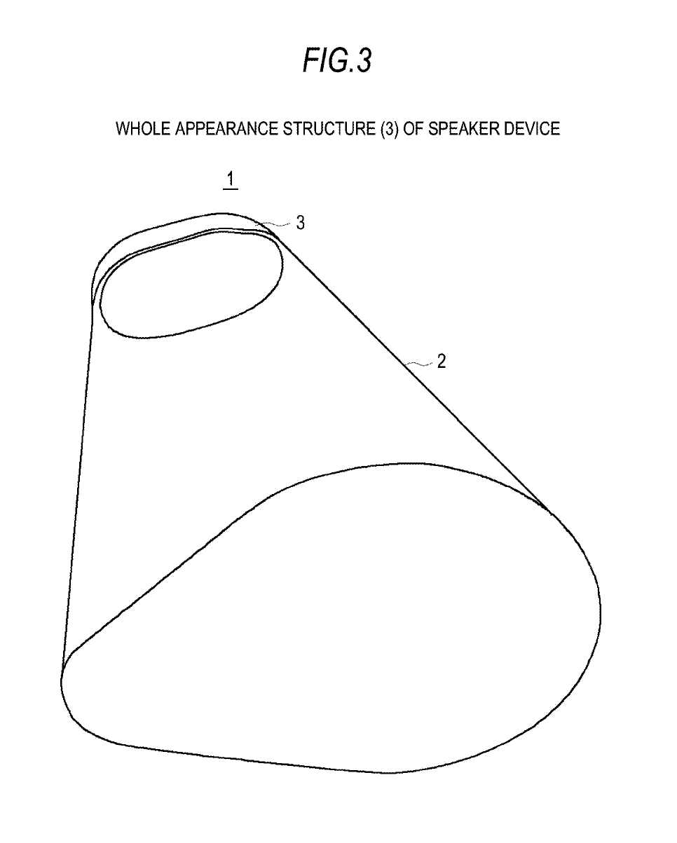

The transparent casing 2 (FIG. 3) opens at one end of an upper portion thereof in the approximately elliptical shape which is the same as the body portion 3 as well as opens at the other end of a lower portion thereof in an approximately tear-drop shape, which differs from the upper portion, in which an outer surface from the upper portion toward the lower portion is formed with a smooth curve.

The transparent casing 2 forms a cylindrical diaphragm in its entirety, which is made of, for example, transparent acrylic resin having translucency or a light guide property in a thickness of 5 mm, and the inside thereof can be visually checked by a user from the outside.

As the transparent casing 2 has a shape opening at the other end of the lower portion, an internal space of the transparent casing 2 is sealed to form a sealed space only when the speaker device 1 is set to a setting target object such as a floor or a wall.

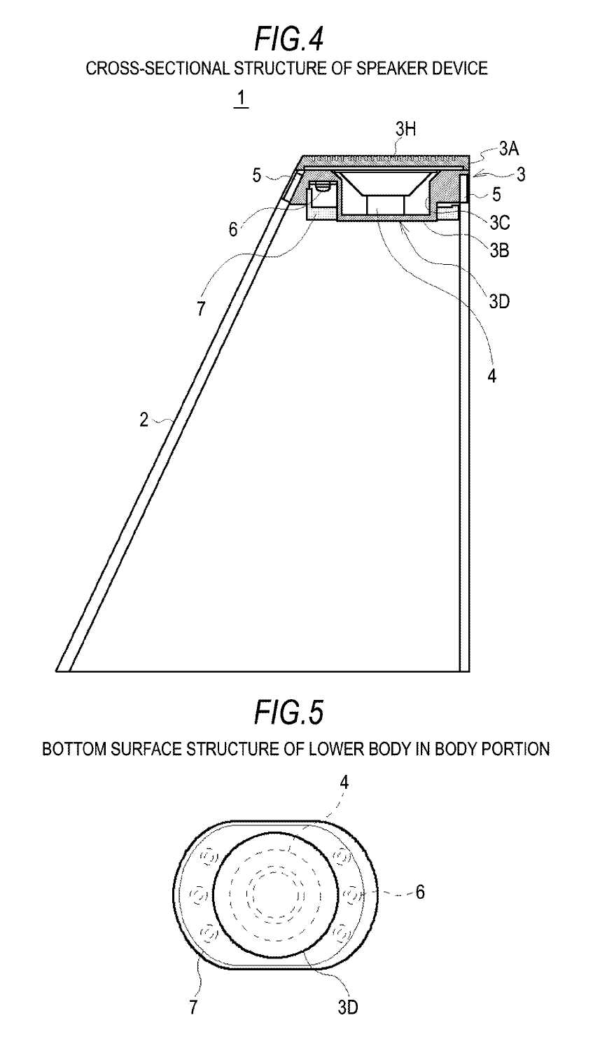

The body portion 3 (FIG. 4) uses, for example, brass as a material, and formed by an upper body 3A made of a thin plate being adhered to a lower body 3B in which a housing hole 3C for housing a speaker unit 4 is formed.

The body portion 3 is housed and fixed in a state in which a front surface of the speaker unit 4 faces upward in the housing hole 3C of the lower body 3B so that a low-frequency sound wave (normal phase) outputted from the front surface of the speaker unit 4 is directly emitted through a minute mesh through-holes 3H (FIG. 1 and FIG. 4) provided on an upper surface of the upper body 3A.

The lower body 3B of the body portion 3 houses a power supply battery and an amplifier though not shown to allow the speaker unit 4 to function as an active speaker. However, it is not always necessary to house the amplifier and it is also preferable that the speaker unit 4 functions as a passive speaker not housing the amplifier.

The lower body 3B of the body portion 3 (FIG. 4 and FIG. 5) is also provided with LED bulbs 6 which are six in total in a form of surrounding the circumference of the housing hole 3C. It is noted that mere LEDs may be used instead of the LED bulbs 6. A diffusion plate 7 having a donut shape is attached to the lower body 3B (FIG. 4) at a protrusion 3D corresponding to the housing hole 3C of the lower body 3B so as to cover the LED bulbs 6.

According to the above structure, the speaker device 1 diffuses irradiated light from the LED bulbs 6 by the diffusion plate 7 and allows the light to transmit inside the transparent casing 2 as diffused light, then, irradiates the opened end side of the transparent casing 2.

Additionally, the lower body 3B of the body portion 3 (FIG. 4) includes piezoelectric actuators 5 which are, for example, four in total thereinside, which are attached so as to abut on an end surface of the upper end portion of the transparent casing 2 at equal intervals on the end surface.

The piezoelectric actuators 5 are a voltage driven type and a displacement direction by a drive rod (not shown) of the piezoelectric actuators 5 is a direction orthogonal to the end surface.

Though four piezoelectric actuators 5 are used in the embodiment, it is not limited to this, and for example, a current-driven type magnetostrictive actuator, electromotive actuator and so on can be used.

In this case, the speaker device 1 uses the voltage-driven type piezoelectric actuators 5, therefore, power consumption is reduced as compared with the current-driven type actuators, as a result, the speaker device 1 obtains advantages that the heat generation amount is reduced as well as the use time of the battery is increased.

In this case, the displacement direction by the piezoelectric actuators 5 is a direction from the upper portion toward the lower portion of the transparent casing 2 (surface direction). As the speaker device 1 has the piezoelectric actuators 5 in the above arrangement state, the transparent casing 2 can be excited from the end surface of the upper end side of the transparent casing 2 with a vibration component in the direction orthogonal to the end surface.

In the transparent casing 2, the end surface of the upper end side is excited by a longitudinal wave, and a vibration elastic wave is propagated in the direction from the upper portion toward the lower portion of the transparent casing 2 to thereby be emitted to the transparent casing 2 as a mixed wave in which the longitudinal wave and a transversal wave are mixed, as a result, a sound image which is uniform over the whole height direction of the transparent casing 2 is formed.

As described above, the transparent casing 2 forms a speaker taking charge of the high frequency side in an audio frequency band and functioning as a tweeter, on the other hand, the speaker unit 4 forms a speaker taking charge of the low frequency side in the audio frequency band and functioning as a woofer.

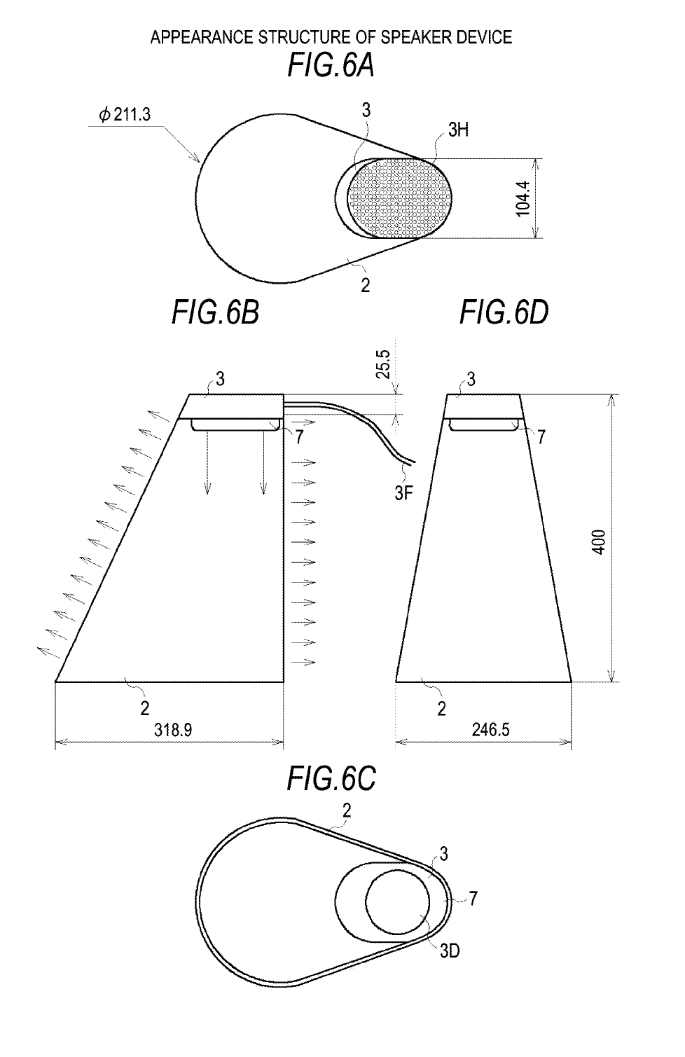

Actually, as shown in FIGS. 6A to 6D, the transparent 2 of the speaker device 1 (FIG. 6B) has a longitudinal length of 318.9 mm and a short-side length of 246.5 mm in an opening portion provided at the lower portion thereof.

In the transparent casing 2 (FIG. 6B), one edge is vertical with respect to a low edge and the other edge slopes with respect to the low edge at a given angle from the upper portion to which the body portion 3 is attached to the lower portion.

Also in the transparent casing 2 (FIG. 6A), not only the other edge slopes with respect to the low edge with a given angle but also a diameter of a large swelled portion of the tear-drop shape is φ211.3 mm, therefore, the transparent casing 2 has a shape which gradually swells and becomes wide toward a bottom hem thereof.

The body portion 3 of the speaker device 1 has a short-side length of 104.4 mm and a thickness of 25.5 mm, in which the diffusion plate 7 slightly protrudes from the lower portion of the body portion 3 and a cord 3F for supplying audio signals to the body portion 3 is connected.

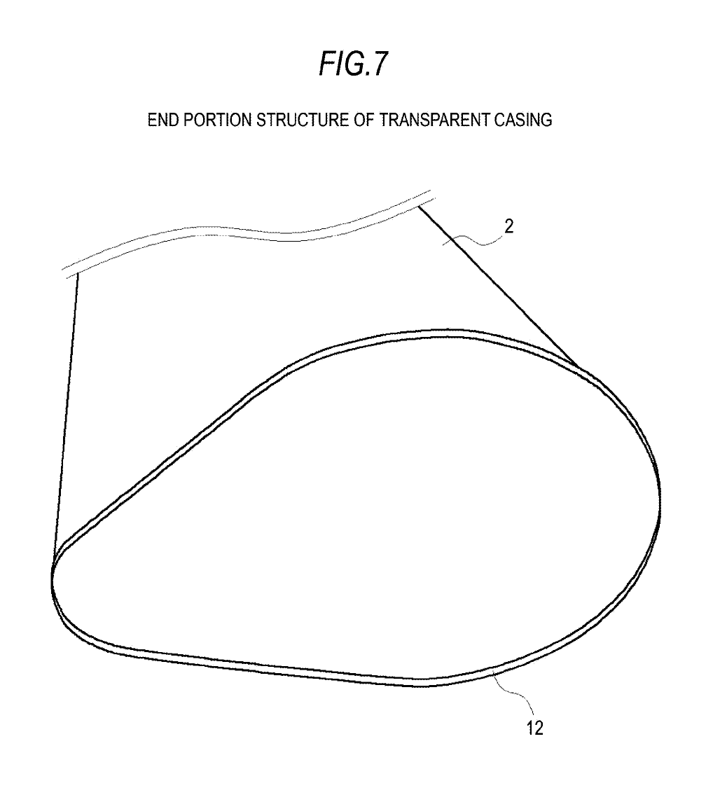

Incidentally, in the transparent casing 2 of the speaker device 1, a rubbery cushioning material 12 is adhered or fit to an peripheral edge of the opened lower end as shown in FIG. 7. Accordingly, in the speaker device 1, when the transparent casing 2 works as the cylindrical diaphragm in a state in which the speaker device 1 is set on the setting target object such as a floor or a wall, vibration of the transparent casing 2 is prevented from being transmitted to the setting surface by the cushioning material 12 to avoid generation of chattering noise before happens.

In the speaker device 1 in the embodiment, the body portion 3 having relatively heavy weight as brass is used as a material (for example, 500 g to 1 kg) is attached in a state of being put on the upper end of the transparent casing 2, therefore, the force of pressing the transparent casing 2 set on the setting target object from above is increased.

Here, as the rubbery cushioning material 12 is fitted to the peripheral edge of the lower end of the transparent casing 2, the setting state between the transparent casing 2 and the setting surface becomes firm. As a result, the speaker device 1 can keep sealing property of the sealed space formed by the transparent casing 2 when the transparent casing 2 operates as the cylindrical diaphragm.

In the speaker device 1 in this case, reverse-phase sound waves outputted from the back surface of the speaker unit 4 are trapped in the sealed space of the transparent casing 2 and are not emitted outside, which prevents occurrence of adverse effects in the reverse-phase sound waves before happens.

The transparent casing 2 is made of not only transparent acrylic resin having translucency or a light guide property but also made of materials including fluorescent paint.

As the fluorescent paint, for example, fluorescent paint for plastics “LumogenF (trademark) Dyes” manufactured by BASF corporation may be used.

Actually, when fluorescent paint which is approximately 0.02% of the mass of the acrylic resin as the material is allowed to be included in the acrylic resin in the transparent casing 2, the transparent casing 2 collects light by the whole surface and emits strong fluorescence at the edge (end surface).

As LumogenF (trademark) Dyes, there exist Orange240 (product name), Yellow083 (product name), Red305 (product name) and so on.

For example, Orange240 (product name) is allowed to be included, the whole transparent casing 2 is seen to be transparent orange as well as emits strong orange fluorescence at the upper end surface and the lower end surface.

Additionally, when characters are written by scratching an outer surface, character portions emit light strongly in the transparent casing 2. The character portions emit light by fluorescent light in the outside, sunlight and so on without turning on the LED bulbs 8.

Accordingly, the speaker device 1 allow the user to view the character portions written in the transparent casing 2 easily under a using environment in which outside light is given to the transparent casing 2 even when the LED bulbs 6 are turned off.

The LumogenF (trademark) Dyes are excellent in light fastness (fluorescence residual ratio), and fluorescence intensity obtained after the transparent casing 2 including Orange240 (product name) is exposed for 2000 hours under certain conditions is 85 when fluorescence intensity before exposure is 100.

### [1-2. Structure of a Drive System of the Speaker Device]

Next, a drive system of the speaker device 1 will be explained in two ways.

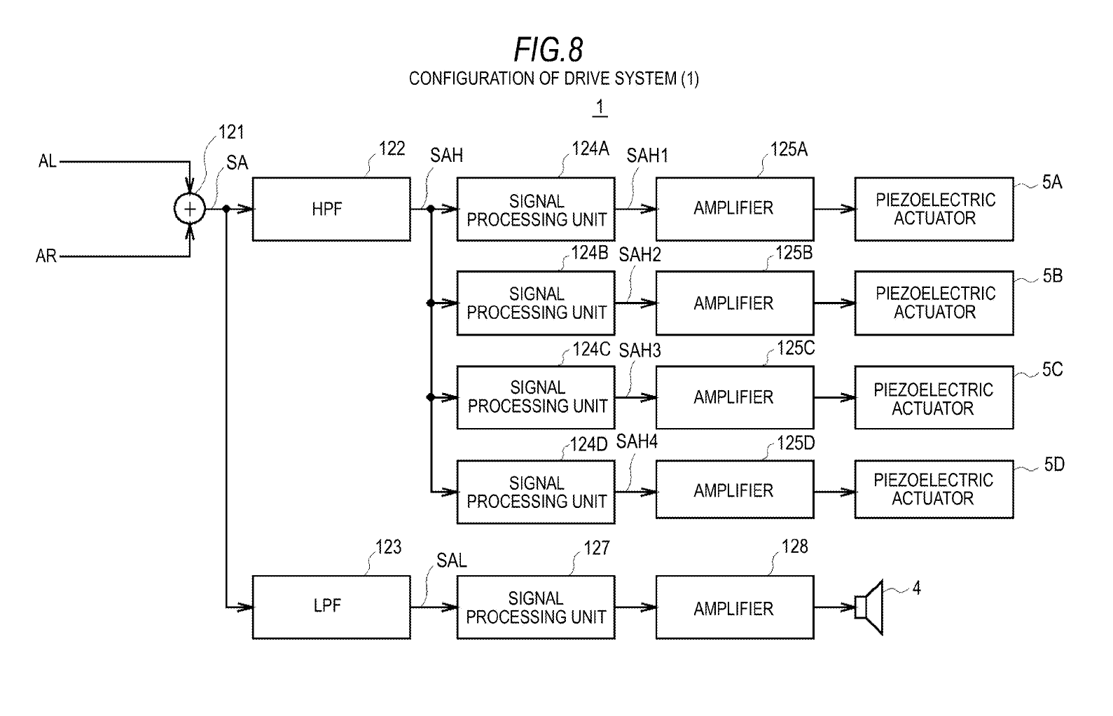

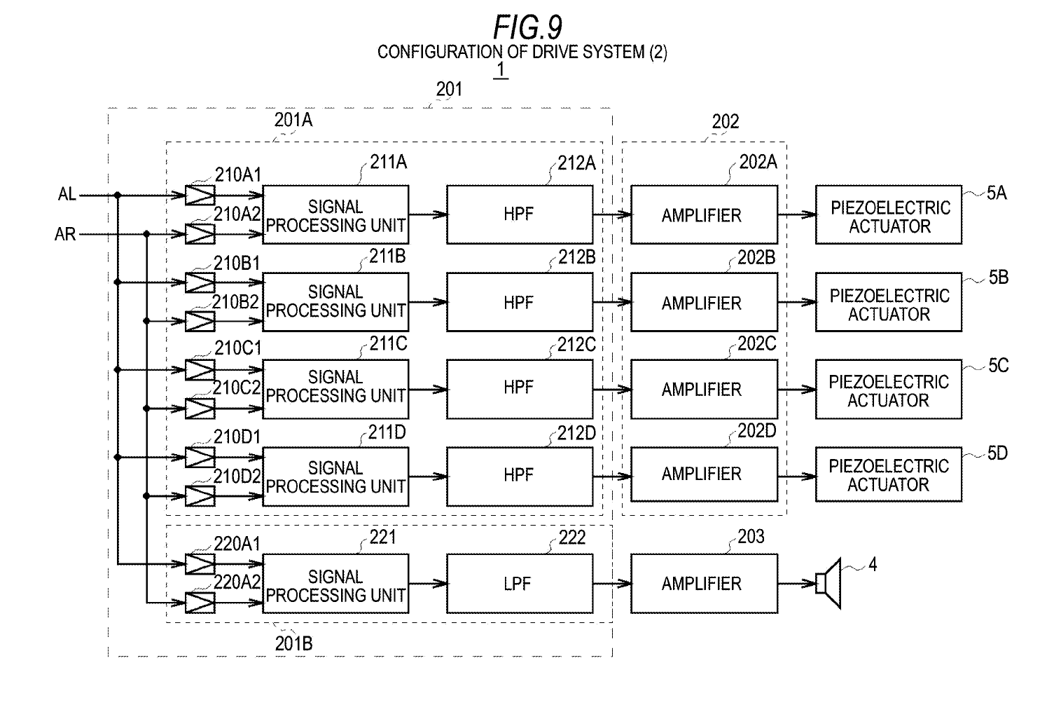

As shown in FIG. 8, in the speaker device 1, for example, a left-audio signal AL and a right-audio signal AR composing a stereo audio signal are inputted to an adder 121 and the left-audio signal AL and the right-audio signal AR are synthesized by the adder 122 to generate a monaural audio signal SA, then, the signal is transmitted to a high-pass filter 122 and a low-pass filter 123.

The high-pass filter 122 extracts only a high-frequency component SAH from the monaural audio signal SA and transmits the signal to four signal processing units 124A to 124D formed by a DSP (Digital Signal Processor) respectively.

The four signal processing units 124A to 124D perform processing of adjusting the level, delay time, frequency characteristics and so on (hereinafter referred to as sound-field control processing) as well as signal correction processing concerning output characteristics of the four piezoelectric actuators 5 with respect to a high frequency component SAH, transmitting high-frequency component signals SAH1 to SAH4 obtained as a result of the above processing to four amplifiers 125A to 125D, respectively.

The amplifiers 125A to 125D amplify the high-frequency component signals SAH1 to SAH4 to a given level and supply the signals to the four piezoelectric actuators 5 (5A to 5D) as drive signals.

According to the above, drive rods (not shown) of the four piezoelectric actuators 5 (5A to 5D) are driven by the individual high-frequency component signals SAH1 to SAH4 to excite the transparent casing 2.

The low-pass filter 123 extracts a low-frequency component SAL from the monaural audio signal SA and transmits the signal to a signal processing unit 127 formed by a DSP. The signal processing unit 127 performs processing of adjusting the level, delay time, frequency characteristics and so on (hereinafter referred to as sound-field control processing) to the low-frequency component SAL and amplify the signal to the given level through an amplifier 128, then, transmits the signal to a speaker unit 4 as a drive signal. Accordingly, the speaker unit 4 is driven by the low-frequency component SAL.

Accordingly, the speaker device 1 drives the speaker unit 4 by the low-frequency component SAL to thereby allow the speaker unit 4 to function as a woofer as well as excites the transparent casing 2 by the high-frequency component signals SAH1 to SAH4 to thereby allow the transparent casing 2 to function as a tweeter, which broadens the reproduction frequency band as the whole speaker device 1.

As the speaker device 1 can excite the transparent casing 2 by using the individual high-frequency component signals SAH1 to SAH 4 with respect to the four piezoelectric actuators 5 as drive signals, it is possible to expand the sound image to the outside of the transparent casing 2.

On the other hand, as shown in FIG. 9, the speaker device 1 roughly includes a DSP block 201, an amplifier block 202 and an amplifier 203. The DSP block 201 includes a signal correction and sound-field control unit 201A on the piezoelectric actuators 5 side and a signal correction and sound-field control unit 201B on the speaker unit 4 side.

The signal correction and sound-field control unit 201A on the piezoelectric actuators 5 side has four signal processing units 211 (211A to 221D) and four high-pass filters 212 (212A to 212D) so as to correspond to four piezoelectric actuators 5 (5A to 5D) respectively.

Furthermore, the signal correction and sound-field control unit 201A includes eight attenuators (210A1, 210A2, 210B1, 210D1, 201D2) for inputting the left-audio signal AL and the right-audio signal AR composing the stereo audio signal to the four signal processing units 211 after being attenuated respectively.

Respective signal processing units 211 (211A to 211D) perform adjustment of the signal level, delay time, frequency characteristics and so on of the left-audio signal AL and the right-audio signal AR to be inputted respectively, mixing processing (sound-field control processing) with respect to the left-audio signal AL and the right-audio signal AR, and further performs signal correction processing concerning output characteristics of the piezoelectric actuators 5 (5A to 5D).

Respective high-pass filters 212 (212A to 212D) extract high-frequency components of audio signals supplied from the signal processing units 211 (211A to 211D) respectively and transmit the signals to respective amplifiers 202A to 202D of the amplifier block 202.

In this case, high-frequency components of audio signals obtained as a result of the sound-field control processing and the signal correction processing performed by the signal correction and sound-field control unit 201A of the DSP block 201 individually are supplied to the four piezoelectric actuators 5 (5A to 5D) after being amplified by the amplifier block 202. The four piezoelectric actuators 5 (5A to 5D) are driven by the high-frequency components obtained by performing the sound-field control processing, thereby increasing wideness in sound due to high-frequency audio output.

On the other hand, the signal correction and sound-field control unit 201B on the speaker unit 4 side includes one signal processing unit 221 and one low-pass filter 222 so as to correspond to the speaker unit 4, and further includes two attenuators 220A1, 220A2 for inputting the left-audio signal AL and the right-audio signal AR composing the stereo audio signal to the signal processing unit 221 after being attenuated respectively.

The signal processing unit 221 performs adjustment of the signal level, delay time, frequency characteristics and so on of the left-audio signal AL and the right-audio signal AR, mixing processing (sound-field control processing) with respect to the left-audio signal AL and the right-audio signal AR, and further performs signal correction processing concerning resonator pipe characteristics. The low-pass filter 222 extracts a low-frequency component of the audio signal supplied from the signal processing unit 221 and transmits the signal to the amplifier 203.

In this case, the low-frequency component of the audio signal obtained by performing the sound-field control processing and the signal correction processing performed by the signal correction and sound-field control unit 201B of the DSP block 201 is supplied to the speaker unit 4 after being amplified by the amplifier 203. The speaker unit 4 is driven by the low-frequency component obtained by performing the sound-field control processing, thereby increasing wideness in sound due to low-frequency audio output.

The positions of the signal processing units 211 (211A to 211D) and the high-pass filters 212 in the signal correction and sound-field control unit 201A may be reversed as well as positions of the signal processing unit 221 and the low-pass filter 222 in the signal correction and sound-field control unit 201B may also be reversed.

### [1-3. Operations of the Speaker Device 1]

Subsequently, operations of the speaker device 1 (FIG. 1 to FIG. 4) will be explained.

In the speaker 1, the four piezoelectric actuators 5 (5A to 5D) provided at the body portion 3 are driven by the left-audio signal AL and the right-audio signal AR and excites the transparent casing 2 from the end surface of the upper end side of the transparent casing 2 with the vibration component in the direction orthogonal to the end surface.

At this time, the end surface of the upper end side of the transparent casing 2 is excited by the longitudinal wave, and the elastic wave (vibration) is propagated in the direction (surface direction) from the upper portion toward the lower portion of the transparent casing 2. Then, the mode conversion in a manner of the longitudinal wave, the transversal wave, the longitudinal wave . . . is repeated when the elastic wave is propagated through the transparent casing 2 to generate the mixed wave of the longitudinal wave and the transversal wave, then, the vibration in the in-surface direction (direction perpendicular to the surface) of the transparent casing 2 is excited by the transversal wave.

According to the above, the speaker device 1 emits sound waves from the transparent casing 2. That is, the speaker device 1 can obtain high-frequency audio output from the outer surface of the transparent casing 2.

At this time, the speaker device 1 is closed by a setting surface with respect to the setting target object at the lower portion of the transparent casing 2, therefore, reverse-phase sound waves generated inside the transparent casing 2 are confined to the inside of the transparent casing 2 and are not emitted to the outside, as a result, good acoustic characteristics can be obtained.

### [1-4. Usage Forms in the Speaker Device]

In the speaker device 1, the lower portion of the transparent casing 2 opens when not set to the setting target object, therefore, it is difficult that the transparent casing 2 realize the function as a cabinet in this state.

However, the speaker device 1 can generate the sealed space of the transparent casing 2 by using the setting surface of the setting target object, therefore, the transparent casing 2 can realize the function as the cabinet despite of the simple structure in which a bottom surface of the transparent casing 2 is not necessary.

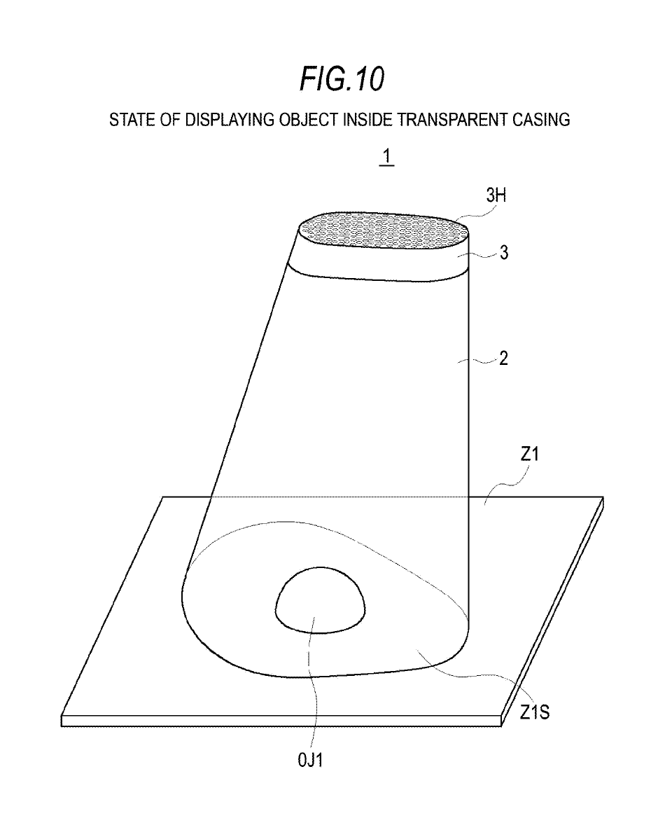

In this case, the speaker device 1 has the structure in which the transparent casing 2 is transparent and the bottom thereof opens, therefore, an object OJI desired to be displayed by the user can be easily displayed in the sealed space formed by the transparent casing 2 and a setting surface Z1S of a setting target object Z1 as well as the object OJI can be taken in and out easily as shown in FIG. 10.

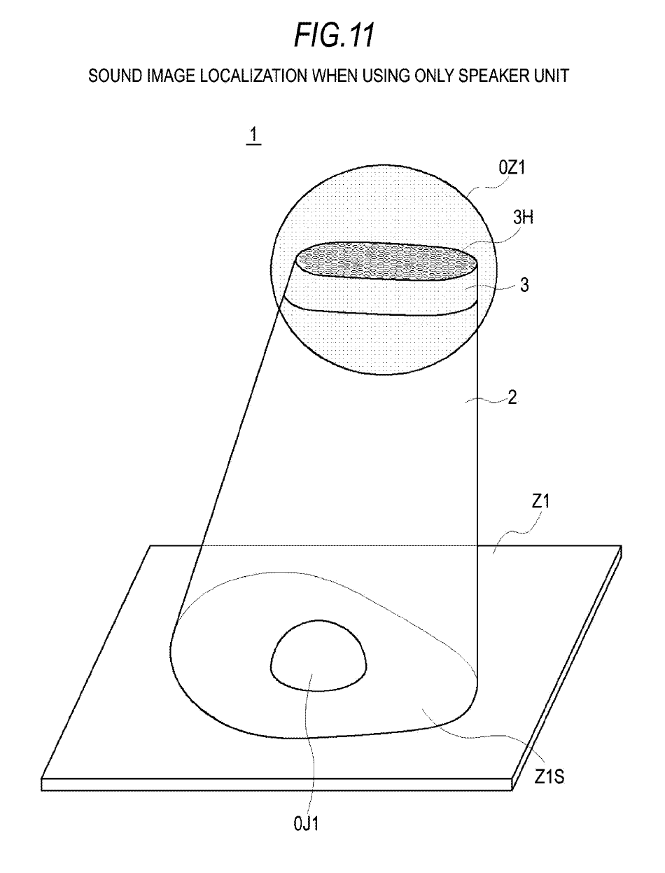

As shown in FIG. 11, when the speaker device 1 outputs high-frequency audio only from the speaker unit 4 without using the transparent casing 2 as the cylindrical diaphragm, a sound image OZ1 is localized in the body portion 3 in which the speaker unit 4 is housed.

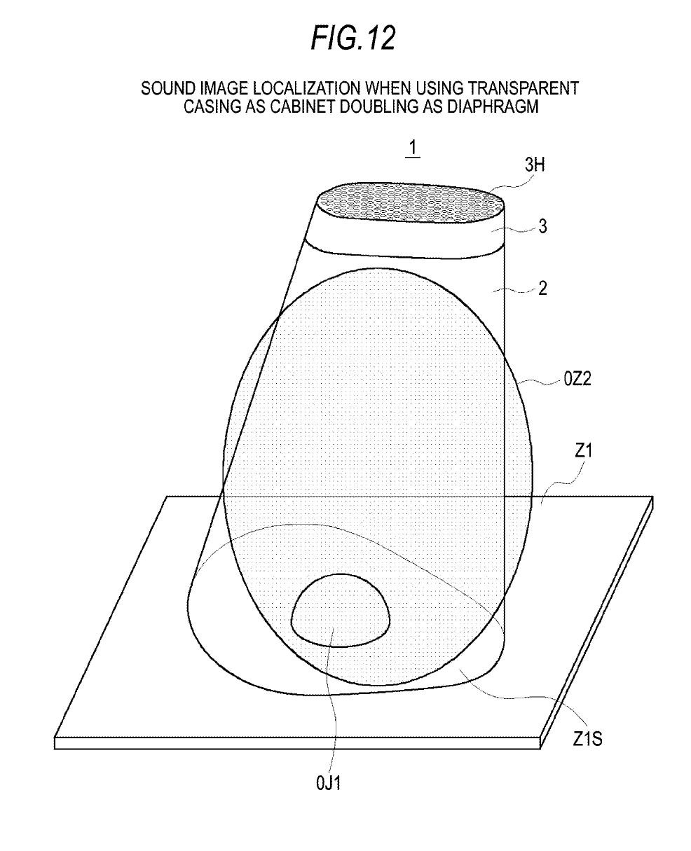

However, as shown in FIG. 12, when the speaker device allows the transparent casing 2 to function as the high-frequency tweeter by using the transparent casing 2 as the cylindrical diaphragm as well as allows the speaker unit 4 to function as the low-frequency woofer, the reproduction frequency band will be broadened as well as a sound image OZ2 can be localized in the transparent casing 2 due to addition of the tweeter.

According to the above, for example, when a doll or the like is displayed as the object OJ1 and high-frequency voice of the doll is outputted from the transparent casing 2 in the speaker device 1, it is possible to give the user a natural impression as if the voice is heard from the vicinity of a mouth of the doll.

Incidentally, in the speaker device 1, delay time of approximately several milliseconds may be added to the low-frequency component SAL to be supplied to the speaker unit 4 by a delay circuit (not shown). According to this, a time point when low-frequency audio is outputted from the speaker unit 4 is later than a time point when high-frequency audio is outputted from the transparent casing 2 in the speaker device 1, therefore, the user can feel the sound image OZ2 at the portion of the transparent casing 2 where high-frequency audio is outputted based on an auditory characteristic of human beings in which the sound image is pulled to the high-frequency.

The speaker device 1 can also realize usage forms such that output guide voice for display contents relating to the object OJI displayed in the sealed space of the transparent casing 2 is outputted by using the transparent casing 2 as the cylindrical diaphragm or that audio is outputted as BGM (Background Music) for the display.

### [1-5. Illumination Effects in the Speaker Device]

In the speaker device 1, irradiated light from the LED bulbs 6 which are six in total attached so as to surround the circumference of the protrusion 3D of the body portion 3 is diffused by the diffusion plate 7 to be transmitted inside the transparent casing 2 as diffused light.

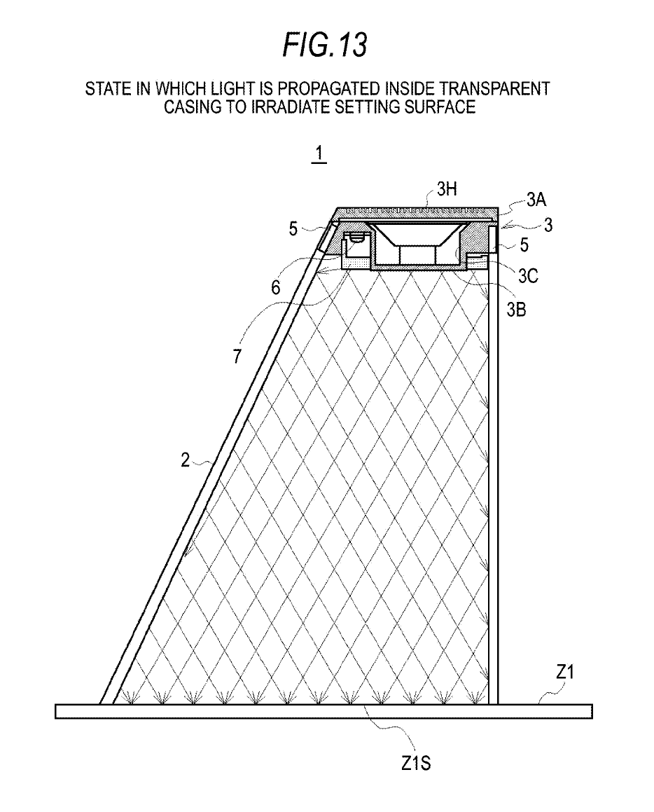

As shown in FIG. 13, the speaker device 1 is configured so that the diffused light diffused by the diffusion plate 7 is reflected at an inside surface of the transparent casing 2, then, reaches the setting surface Z1S of the setting target object Z1 to irradiate the setting surface Z1S.

Here, the transparent casing 2 is made of acrylic resin having translucency or a light guide property as described above, therefore, the diffusion light diffused by the diffusion plate 7 is allowed to reach the setting surface Z1S of the setting target object Z1 effectively after being reflected at the inside surface of the transparent casing 2.

As the rubbery cushioning material 12 is fitted on the peripheral edge of the opened lower end of the transparent casing 2 in this case, the diffused light reaching the setting surface Z1S can be prevented from leaking from the opened end of the transparent casing 2.

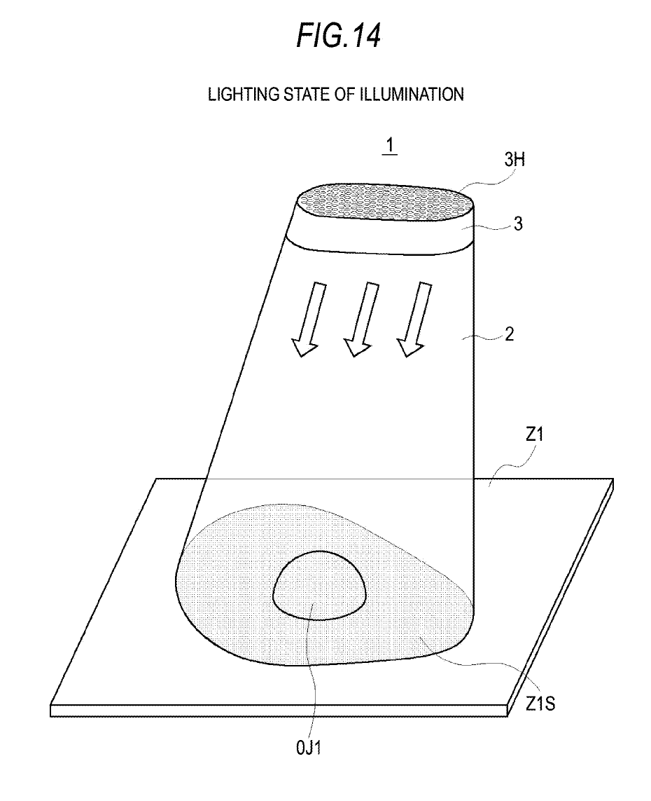

According to the above, the speaker device 1 can form an illumination state as if the setting surface Z1S is floating as shown in FIG. 14.

Actually, visual effects as if the setting surface Z1S is a stage for the object OJ1 as a display are brought about to make the object OJ1 as the display look much better in the speaker device 1 when the setting surface Z1S inside the transparent casing 2 is irradiated.

### [1-6. Operations and Effects]

In the above structure, the sealed space is formed by the transparent casing 2 and the setting surface Z1S of the setting target object Z1 in the speaker device 1 only when the transparent casing 2 having the cylindrical shape which opens at one end side is set to the setting target object Z1 in the speaker device 1, as a result, the transparent casing 2 functions as a cabinet of the speaker unit 4.

Accordingly, while the speaker device 1 has a simple structure not having the bottom surface of the transparent casing 2, the transparent casing 2 surely forms the sealed space when set to the setting target object Z1 to thereby function as the cabinet for the speaker unit 4, therefore, the object OJ1 can be displayed easily inside the transparent casing 2 without damaging the function as the speaker.

Additionally, as the speaker device 1 has the structure in which the transparent casing 2 functions as the cabinet only when the transparent casing 2 having the cylindrical shape which opens at one end side is set to the setting target object Z1, the setting place does not matter despite of the simple structure in which the bottom surface is not necessary, as long as there is the setting surface such as the floor, the wall or the ceiling.

Furthermore, in the speaker device 1, the transparent casing 2 set to the setting target object Z1 is strongly pressed from above by the relatively heavy body portion 3 made of brass, thereby preventing the vibration of the transparent casing 2 from being transmitted to the setting surface Z1S due to the cushioning material 12 fitted to the opening edge of the transparent casing 2 and obtaining good acoustic characteristics while positively maintaining the sealed space by the transparent casing 2.

Additionally, the speaker device 1 irradiates the setting surface Z1S of the setting target object Z1 by the LED bulbs 6 provided at the lower body 3B of the body portion 3 and diffusion light obtained through the diffusion plate 7, thereby allowing the setting surface Z1S to look as if it is floating such as a stage, which makes the display look much better.

In this case, the speaker device 1 can localize the sound image on the transparent casing 2 side functioning as the tweeter, therefore, the sound image is consequently localized in the vicinity of the display, which can create the sense of unity between the object and output audio.

Additionally, the speaker unit 4 is not seen from the outside in the speaker device 1, therefore, the speaker device 1 gives the user an impression as if the speaker device 1 is a show window for decorating the display and the excellent sense of design as interior decoration can be obtained.

According to the above structure, the speaker device 1 is configured so that the transparent casing 2 functions as the cabinet only when the transparent casing 2 opening at one end side is set, therefore, it is possible to put the display inside the transparent casing 2 while realizing the function as the speaker.

Also in the speaker device 1, the transparent casing 2 functions as the cabinet for the speaker unit 4 as well as the transparent casing 2 itself functions as the tweeter only when the transparent 2 is set to the setting target object Z1, therefore, the speaker having a wide reproduction frequency band can be realized despite of the simple structure with good sense of design.

### 2. Other Embodiments

In the above embodiment, the case in which the speaker unit 4 housed in the body portion 3 is attached in a state in which the front surface thereof faces upward has been described, however, the invention is not limited to this and the speaker unit 4 may be attached in a state in which the front surface thereof faces downward.

In the above embodiment, the case of using the transparent casing 2 has been described, however, the invention is not limited to this, and it is not always necessary that the casing is transparent and casings of given colors may be used.

Furthermore, in the above embodiment, the case in which the object OJ1 is put in the sealed space formed between the transparent casing 2 and the setting surface Z1S to be displayed has been described. However, the invention is not limited to this, and it is also preferable to use the transparent casing 2 having a larger internal volume by the volume of the object OJ1 in advance for preventing the increase of a low-range resonance frequency f0 from the speaker unit 4 because the internal volume of the sealed space formed by the transparent casing 2 is reduced when the object OJ1 is displayed.

As another embodiment, it is preferable that a knob (not shown) is provided on the surface of the body portion 3 of the speaker device 1 and the low-range resonance frequency f0 reduced due to the object OJ1 displayed in the sealed space of the transparent casing 2 is adjusted through the signal processing unit 127 (FIG. 8) by allowing the user to operate the knob to obtain acoustic characteristics desired by the user.

In this case, the speaker device 1 may adjust the level, frequency characteristics and the like with respect to the low-frequency component SAL of the signal processing unit 127 in accordance with the user operation to the knob.

Also in the above embodiment, the case of using the transparent casing 2 having the approximately tear-drop shape which becomes gradually wide toward the bottom hem has been described. However, the invention is not limited to this and it is preferable to use the transparent casings 2 having a mere cylinder shape, a triangular pyramid shape and other various shapes as long as the lower end is opened.

Further in the above embodiment, the case in which the speaker device according to the embodiment of the invention is configured to include the cabinet 2 as a casing and the speaker unit 4 as a sounding body has been described. However, the invention is not limited to this and the speaker device may use casings and the sounding bodies having other various structures and shapes.

The speaker device according to the embodiment of the invention is not only used as a stand-alone speaker device but also can be applied to a speaker device incorporated in audio visual apparatus such as a television.

The present application contains subject matter related to that disclosed in Japanese Priority Patent Application JP 2010-091553 filed in the Japan Patent Office on Apr. 12, 2010, the entire contents of which is hereby incorporated by reference.

It should be understood by those skilled in the art that various modifications, combinations, sub-combinations and alterations may occur depending on design requirements and other factors insofar as they are within the scope of the appended claims or the equivalents thereof.

What is claimed is:

1. A speaker device comprising:
a casing having a cylindrical shape which opens at one end side; and
a sounding body arranged at the other end side of the casing and driven based on an audio signal,
wherein a sealed space is formed by the casing and a setting surface when the casing is set, which functions as a cabinet.

2. The speaker device according to claim 1,
wherein the casing is made of a transparent member.

3. The speaker device according to claim 2,
wherein a cushioning material is attached to an end of the casing abutting when the casing is set.

4. The speaker device according to claim 3,
wherein a body portion for concealing the sounding body arranged at the other end side is provided at the other end side.

5. The speaker device according to claim 4,
wherein the body portion houses not only the sounding body but also a power supply battery and an amplifier, which functions as an active speaker.

6. The speaker device according to claim 4,
wherein the body portion is provided with a light source.

7. The speaker device according to claim 6,
wherein the light source of the body portion irradiates the inside of the setting surface when the casing is set.

8. The speaker device according to claim 5, further comprising:
an actuator in which a transmission unit transmitting displacement output to the casing is arranged in a state of abutting on an end surface directly or indirectly for exciting the casing by a vibration component in a direction orthogonal to the end surface of the casing and the transmission unit is driven based on an audio signal,
wherein the casing vibrates as a diaphragm in its entirety by being excited by the actuator through the transmission unit.
